(19) United States
(12) Patent Application Publication
(10) Pub. No.: US 2026/0275495 A1
(43) Pub. Date: Sep. 17, 2026

(54) VAPOR DEPOSITION APPARATUS AND PRODUCTION METHOD FOR DISPLAY DEVICE

(71) Applicant: SHARP DISPLAY TECHNOLOGY CORPORATION, Kameyama City, Mie (JP)

(72) Inventors: Masahiro INUZUKA, Kameyama City, Mie (JP); Manabu NIBOSHI, Kameyama City, Mie (JP); Shinichi ESUMI, Kameyama City, Mie (JP); Hideyuki SUZUKI, Kameyama City, Mie (JP)

(21) Appl. No.: 19/167,918

(22) PCT Filed: Mar. 24, 2023
(86) PCT No.: PCT/JP2023/011687

§ 371 Date: Sep. 23, 2025

(51) Int. Cl. C23C 14/24; H10K 71/16

(52) U.S. Cl. CPC C23C 14/243; H10K 71/164

(57) ABSTRACT

A vapor deposition apparatus includes: a crucible including an opening configured to release a vapor deposition material toward a vapor deposition target; and a lid portion configured to move between a blocking position, the vapor deposition material being prevented from reaching the vapor deposition target at the position and an opening position, the vapor deposition material reaching the vapor deposition target at the position. The lid portion includes a top plate portion overlapping the opening when the opening is viewed from a position where the vapor deposition target is disposed when the lid portion is at the blocking position, at least one hole communicating through the top plate portion, and at least one cap configured to close the hole in an openable and closable manner.

### TECHNICAL FIELD

The disclosure relates to a vapor deposition apparatus for forming a vapor deposition film, and a manufacturing method for a display device using the vapor deposition apparatus.

### BACKGROUND ART

As a forming method for a thin film, vapor deposition is known in which a material in a crucible is melted and evaporated by a heater, and the material is brought into contact with a surface of an object located above the crucible and solidified, thereby forming the thin film containing the material on the surface of the object. In particular, in a manufacturing method for a display device including a light-emitting element such as an OLED, the vapor deposition using a vapor deposition apparatus may be adopted for forming layers of the light-emitting element in order to reduce deterioration of the layers.

In a forming step of a vapor deposition film by using the vapor deposition apparatus, there is a period in which vapor deposition is not performed on a substrate, such as a period until a film formation rate is stabilized by heating a vapor deposition source, or a period during which the substrate in a vacuum chamber is changed. In order to reduce contamination of the interior of the vacuum chamber and the like due to a vapor deposition material during this period, it is conceivable to cover an opening of the crucible with a lid.

However, while the opening of the crucible is covered with the lid in the forming step of the vapor deposition film, the vapor deposition source continues to sublimate and adheres to the lid. In this case, it is necessary to perform maintenance in which the lid is periodically cleaned and the vapor deposition material is removed from the lid. PTL 1 discloses, as a method of the maintenance, a method in which the lid is moved to a recovery mechanism and then the lid is heated to evaporate the vapor deposition material again and remove the vapor deposition material from the lid.

### CITATION LIST

### Patent Literature

PTL1: JP 10-168559 A

### SUMMARY

### Technical Problem

In the case of the method described in PTL 1, in order to clean the lid, a step of moving the lid to the recovery mechanism and heating the lid is required. In addition, in the method, the recovery mechanism and a heater for heating the lid are separately required. Thus, it is difficult to easily remove foreign matters from the lid by the above method, and maintainability of the lid is deteriorated.

### Solution to Problem

A vapor deposition apparatus according to one aspect of the disclosure includes a crucible including an opening for releasing a vapor deposition material toward a vapor deposition target, and a lid portion for moving between a blocking position that is a position where the vapor deposition material is prevented from reaching the vapor deposition target and an opening position that is a position where the vapor deposition material reaches the vapor deposition target, in which the lid portion includes a top plate portion overlapping the opening when the opening is viewed from a position where the vapor deposition target is disposed when the lid portion is at the blocking position, at least one hole communicating through the top plate portion, and at least one cap for closing the hole in an openable and closable manner.

### Advantageous Effects of Disclosure

A vapor deposition material adhering to a lid portion can be more easily removed and maintainability of the lid portion is improved.

### BRIEF DESCRIPTION OF DRAWINGS

FIG. 1 is a schematic side cross-sectional view of a vapor deposition apparatus according to a first embodiment.

FIG. 2 is a schematic side cross-sectional view of a display device according to embodiments.

FIG. 3 is a schematic side cross-sectional view of a lid portion according to the first embodiment.

FIG. 4A is a schematic plan view of a second space when the lid portion according to the first embodiment is at a blocking position.

FIG. 4B is a schematic plan view of the second space when the lid portion according to the first embodiment is at an opening position.

FIG. 5 is a schematic side cross-sectional view of the crucible and the lid portion, illustrating a state in which the lid portion according to the first embodiment blocks the vapor deposition material released from the crucible at the blocking position.

FIG. 6 is a schematic side cross-sectional view of the lid portion, illustrating a state of removing an inner lid of the lid portion according to the first embodiment from an outer lid.

FIG. 7 is a schematic side cross-sectional view illustrating a state of cleaning the inner lid of the lid portion according to the first embodiment.

FIG. 8 is a graph showing a relationship between a cleaning time of the lid portion and a vapor deposition material removal rate in cleaning steps according to Example and Comparative Example.

FIG. 9 is a schematic side cross-sectional view of the lid portion according to a second embodiment.

FIG. 10 is a schematic side cross-sectional view of the crucible and the lid portion, illustrating a state in which the lid portion according to the second embodiment blocks the vapor deposition material released from the crucible at the blocking position.

FIG. 11 is a schematic side cross-sectional view illustrating a state of cleaning the inner lid of the lid portion according to the second embodiment.

FIG. 12 is a schematic side cross-sectional view of the lid portion according to a third embodiment.

### DESCRIPTION OF EMBODIMENTS

### First Embodiment

### Display Device

Embodiments of the disclosure will be described below with reference to the drawings. In each drawing, the same components are denoted by the same reference numerals and signs, and description thereof is omitted.

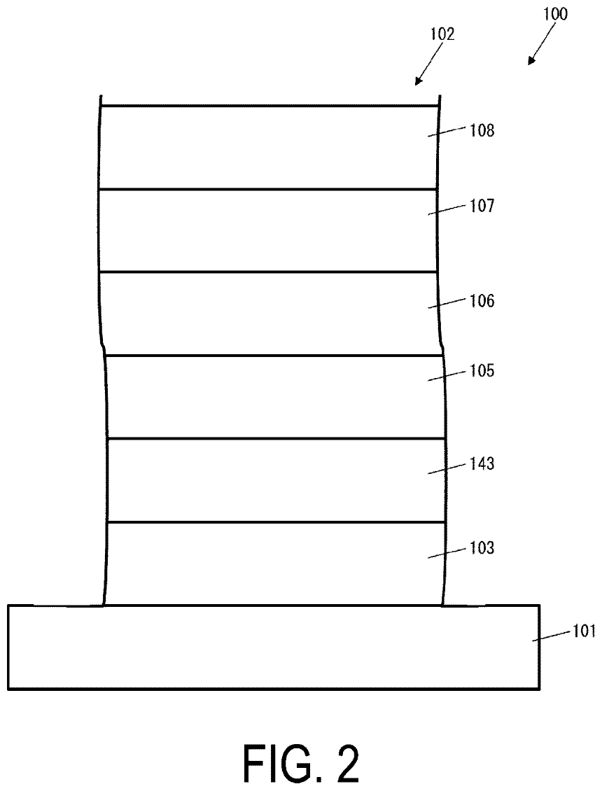

A display device according to the present embodiment will be described with reference to FIG. 2. FIG. 2 is a schematic side cross-sectional view of a display device 100 according to the present embodiment. The display device 100 is a device that can be used as a display of, for example, a television or a smartphone. The display device 100 includes a substrate 101 that is, for example, a TFT substrate, and a plurality of light-emitting elements 102 formed on the substrate 101.

The light-emitting element 102 includes, for example, an anode 103 that is a first electrode, a hole injection layer 104, a hole transport layer 105, a light-emitting layer 106, an electron transport layer 107, and a cathode 108 that is a second electrode sequentially from the substrate 101 side. Note that a structure of the light-emitting element 102 is not limited to the above configuration, and the light-emitting element 102 may include the cathode 108, the electron transport layer 107, the light-emitting layer 106, the hole transport layer 105, the hole injection layer 104, and the anode 103 sequentially from the substrate 101 side. As long as the light-emitting element 102 includes at least the light-emitting layer 106 between the anode 103 and the cathode 108, the light-emitting element 102 need not necessarily include at least one of the hole injection layer 104, the hole transport layer 105, and the electron transport layer 107. In other words, the light-emitting element 102 includes a function layer including at least the light-emitting layer 106 between the anode 103 and the cathode 108. Further, the light-emitting element 102 may include a further function layer including, for example, an electron injection layer between the electron transport layer 107 and the cathode 108.

The display device 100 applies a voltage between the anode 103 and the cathode 108 of each light-emitting element 102 via a driver (not illustrated) or the like formed on the substrate 101. In each light-emitting element 102 to which a voltage is applied, holes are injected from the anode 103 into the light-emitting layer 106 through the hole injection layer 104 and the hole transport layer 105, and electrons are injected from the cathode 108 into the light-emitting layer 106 through the electron transport layer 107. The light-emitting layer 106 includes, for example, a light-emitting material containing an organic light-emitting material, and emits light by excitons generated by recombination of injected holes and electrons. At least one of the anode 103 and the cathode 108 is a transmissive electrode having an optical transparency, and the light-emitting element 102 extracts light emitted from the light-emitting layer 106 to the transmissive electrode side. Thus, the display device 100 performs display by individually extracting light from each light-emitting element 102.

Examples of a manufacturing method for the display device 100 according to the present embodiment include a method for sequentially performing a film formation of the layers of the light-emitting element 102 on the substrate 101. Here, in particular, in the manufacturing method for the display device 100 according to the present embodiment, at least one layer of the layers of the light-emitting element 102 is formed by vapor deposition using a vapor deposition apparatus described later.

### Vapor Deposition Apparatus: Overview

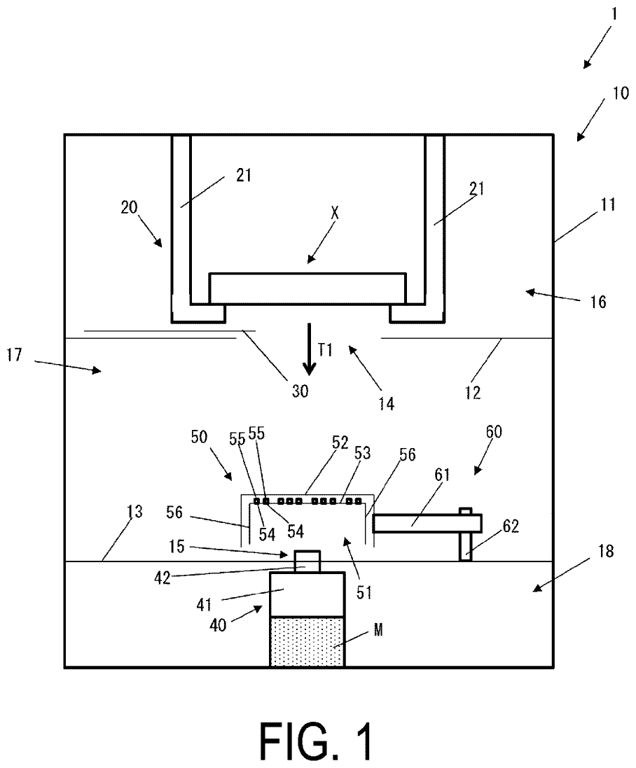

A vapor deposition apparatus according to the present embodiment will be described with reference to FIG. 1. FIG. 1 is a schematic side cross-sectional view of a vapor deposition apparatus 1 according to the present embodiment. FIG. 1 also illustrates a vapor deposition target X described later on a surface of which a vapor deposition film is formed by the vapor deposition apparatus 1, and a vapor deposition material M, which is a material of the vapor deposition film and is stored in the interior of a crucible body 41 described later.

The vapor deposition apparatus 1 includes a vacuum chamber 10, a holding portion 20, a shutter 30, a crucible 40, a lid portion 50, and a lid holding portion 60.

In particular, the vapor deposition apparatus 1 includes the crucible 40 and the lid portion 50. As described later, the crucible 40 includes an opening 42 for releasing the vapor deposition material M toward the vapor deposition target X. The lid portion 50 moves between a blocking position that is a position where the vapor deposition material M is prevented from reaching the vapor deposition target X and an opening position where the vapor deposition material M reaches the vapor deposition target X. The lid portion 50 includes a top plate portion 53, at least one hole 54, and at least one cap 55. When the lid portion 50 is at the blocking position, the top plate portion 53 is at a position overlapping the opening 42 when the opening 42 is viewed from a position where the vapor deposition target X is disposed. The hole 54 communicates through the top plate portion 53, and the cap 55 closes the hole 54 in an openable and closable manner. With the above configuration, the vapor deposition apparatus 1 according to the present embodiment enables more efficient removal of the vapor deposition material M from the lid portion 50, and improves the maintainability of the lid portion 50. Hereinafter, the vapor deposition apparatus 1 including the above will be described in detail.

### Vapor Deposition Apparatus: Vacuum Chamber

The vacuum chamber 10 includes a housing 11, a first partition 12, a second partition 13, a first partition opening 14, and a second partition opening 15.

The housing 11 is hollow, and the first partition 12 and the second partition 13 extend substantially parallel to an upper face of a bottom portion of the housing 11 in the interior of the housing 11, and partition the interior of the housing 11 into a plurality of spaces. Thus, the interior of the housing 11 is partitioned into a first space 16 above the first partition 12, a second space 17 between the first partition 12 and the second partition 13, and a third space 18 below the second partition 13.

However, the first partition opening 14 is formed in the first partition 12, and the first space 16 and the second space 17 partitioned by the first partition 12 communicate with each other through the first partition opening 14. In addition, a second partition opening 15 is formed in the second partition 13. The opening 42 of the crucible 40 described later is inserted into the second partition opening 15 to be sealed. Thus, the second space 17 and the third space 18 do not communicate with each other.

The housing 11 may include an entrance communicating with the first space 16 and a door portion that seals the entrance in an openable and closable manner. The vapor deposition target X may be introduced into the interior of the vacuum chamber 10 through the entrance of the housing 11. In the vacuum chamber 10, in a state in which the vapor deposition target X is held in the first space 16 by the holding portion 20 described later and the entrance is sealed by the door portion, at least the first space 16 and the second space 17 in the interior of the housing 11 can be made vacuum by a pump (not illustrated). The shape of the housing 11 may have a cylindrical shape from the viewpoint of maintaining a strength when the first space 16 and the second space 17 are made vacuum, but is not limited thereto, and may have a rectangular parallelepiped shape.

### Vapor Deposition Apparatus: Holding Portion

The holding portion 20 includes an arm 21 formed in the first space 16. For example, the arm 21 is formed on an upper inner face of the housing 11. The vapor deposition target X is placed on the arm 21 with a surface of the vapor deposition target X on which the vapor deposition film is formed facing the second space 17 side, so that the holding portion 20 holds the vapor deposition target X in the first space 16.

### Vapor Deposition Apparatus: Shutter

The shutter 30 is moved by a driving portion (not illustrated) between a blocking position where the shutter 30 overlaps the first partition opening 14 and an opening position where the shutter 30 does not overlap the first partition opening 14 when the first partition opening 14 is viewed from the vapor deposition target X held by the holding portion 20. When the shutter 30 is at the opening position, the vapor deposition target X held by the holding portion 20 faces the second space 17 with the first partition opening 14 interposed therebetween. In the present specification, a case in which the shutter 30 is at the opening position will be described unless otherwise specified.

### Vapor Deposition Apparatus: Crucible

The crucible 40 includes a crucible body 41 that is a hollow container, and the opening 42 that communicates the inside and the outside of the crucible body 41 and has, for example, a cylindrical shape. In the present embodiment, the vapor deposition material M that has, for example, sublimability and is solid at room temperature is stored in the interior of the crucible body 41. The crucible body 41 is located in the interior of the third space 18, and the opening 42 is inserted into the second partition opening 15 to seal the second partition opening 15 as described above. Thus, the interior of the crucible body 41 and the second space 17 communicate with each other through the opening 42. The crucible 40 heats the interior of the crucible body 41 by a heater (not illustrated), thereby heating and sublimating the vapor deposition material M stored in the interior of the crucible body 41. The opening 42 releases the vapor deposition material sublimated in the interior of the crucible body 41 toward the second space 17, in other words, releases the vapor deposition material M toward the vapor deposition target X. The shape of the crucible body 41 may be a cylindrical shape, a rectangular parallelepiped shape, or the like and is not particularly limited. The materials of portions of the crucible 40 contain, for example, titanium, but are not particularly limited.

### Vapor Deposition Apparatus: Lid Portion and Lid Holding Portion

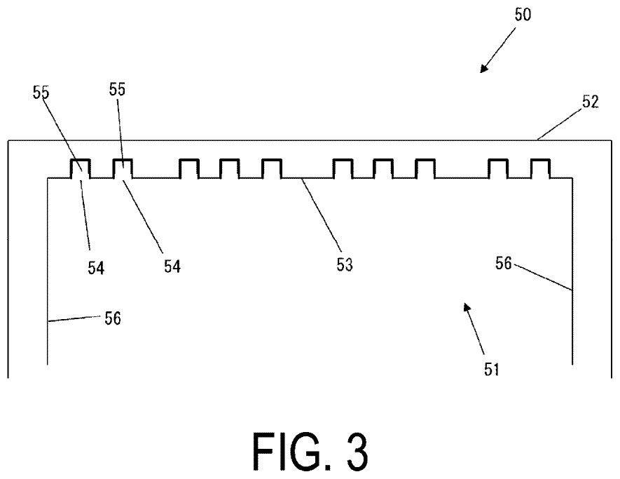

The lid portion 50 according to the present embodiment will be described in detail with reference to FIG. 3 in addition to FIG. 1. FIG. 3 is a schematic cross-sectional view of the lid portion 50, and is an enlarged schematic view of the vicinity of the lid portion 50 in the cross-section illustrated in FIG. 1. Hereinafter, the schematic side cross-sectional view including FIG. 3 illustrates a cross-section corresponding to the cross-section illustrated in FIG. 1.

The lid portion 50 includes an inner lid 51 and an outer lid 52. The inner lid 51 includes a top plate portion 53, a plurality of the holes 54, a plurality of the caps 55, and side portions 56 with respect to the top plate portion 53.

The top plate portion 53 is, for example, a plate-shaped member having a disk shape. Each of the holes 54 communicates through the top plate portion 53. The caps 55 are formed in the same number as the number of the holes 54, and close the holes 54, respectively, in an openable and closable manner. In other words, the lid portion 50 according to the present embodiment includes the plurality of holes 54 and the plurality of caps 55, and each of the caps 55 closes a respective one of the holes 54 in an openable and closable manner. The cap 55 may be rotatably constrained to the top plate portion 53, for example. FIGS. 1 and 3 illustrate a state in which all the caps 55 close the corresponding holes 54.

The outer lid 52 detachably supports the inner lid 51 by a support mechanism (not illustrated). In particular, the outer lid 52 supports the inner lid 51 so as to cover the top plate portion 53 of the inner lid 51 and the outer sides of the side portions 56.

The materials of portions of the lid portion 50 are not particularly limited. However, as described later, from the viewpoint of reducing deformation of the lid portion 50 in a case in which the sublimated vapor deposition material M adheres to the portions of the lid portion 50, the materials of the portion of the lid portion 50 may include a metal material including SUS, having low expansion.

Referring back to FIG. 1, the lid portion 50 is held to the vacuum chamber 10 by the lid holding portion 60. The lid holding portion 60 includes, for example, a beam 61 and a beam shaft 62. The beam 61 has, for example, a straight rod shape, and the outer lid 52 is attached to one end of the beam 61. The beam shaft 62 is fixed to, for example, the upper face of the second partition 13, and constrains the other end of the beam 61 on a side opposite to the side on which the outer lid 52 is attached. In particular, the beam shaft 62 rotatably constrains the beam 61 with an up-down direction as an axis.

Thus, the beam 61 rotates about the beam shaft 62, so that the outer lid 52 attached to the beam 61 moves. When the inner lid 51 is attached to the outer lid 52, the inner lid 51 and the outer lid 52 move together. Thus, the vapor deposition apparatus 1 can control the position of the lid portion 50 through the control of the rotation of the beam 61 about the beam shaft 62.

For example, the beam 61 may be integral with the outer lid 52. The beam 61 may be detachable together with the lid portion 50 from the beam shaft 62.

### Vapor Deposition Apparatus: Blocking Position and Opening Position of Lid Portion

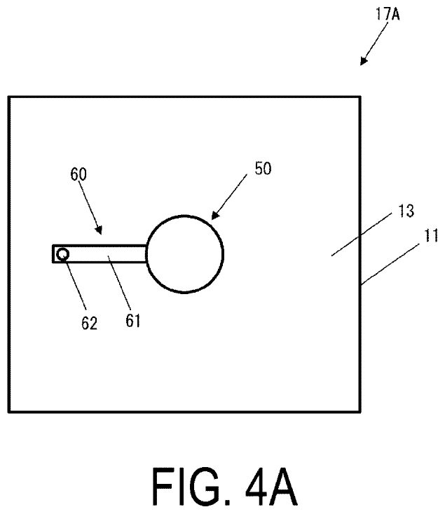

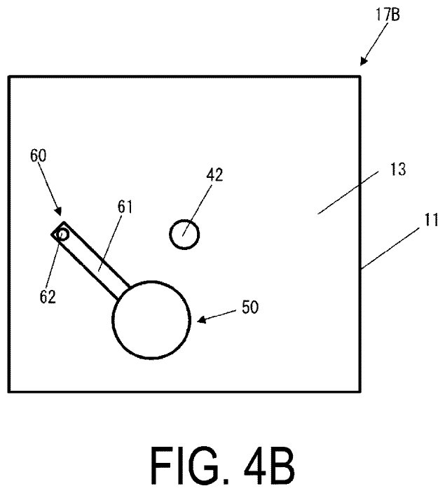

In particular, the lid portion 50 moves between the blocking position and the opening position in accordance with the movement of the beam 61 of the lid holding portion 60. Next, the blocking position and the opening position will be described in more detail with reference to FIGS. 4A and 4B. Both FIGS. 4A and 4B are schematic plan views when the second space 17 is viewed toward a direction T1 illustrated in FIG. 1, which is a direction from a position where the vapor deposition target X is held toward the crucible 40. In particular, FIG. 4A illustrates a schematic plan view of the second space 17A when the lid portion 50 is at the blocking position, and FIG. 4B illustrates a schematic plan view of the second space 17B when the lid portion 50 is at the opening position.

As illustrated in FIG. 4A, when the lid portion 50 is at the blocking position, the lid portion 50 is at a position where the lid portion 50 hides the opening 42 when the opening 42 of the crucible 40 is viewed from the position where the vapor deposition target X is disposed, in other words, when the opening 42 is viewed in the direction T1. In particular, when the lid portion 50 is at the blocking position, the top plate portion 53 overlaps the opening 42 when the opening 42 is viewed in the direction T1. In addition, in a state in which the lid portion 50 is at the blocking position, the outer lid 52 supports the inner lid 51 on a side opposite to the opening 42 with respect to the inner lid 51, in other words, on a side of the vapor deposition target X.

Thus, when the lid portion 50 is at the blocking position, the lid portion 50 is present on a path along which the vapor deposition material M released from the opening 42 reaches the vapor deposition target X. Thus, the blocking position of the lid portion 50 is a position where the lid portion 50 prevents the vapor deposition material M from reaching the vapor deposition target X.

Here, the beam 61 rotates around the beam shaft 62 from the state in which the lid portion 50 is at the blocking position, so that the lid portion 50 moves from the blocking position to the opening position illustrated in FIG. 4B. When the lid portion 50 is at the opening position, the lid portion 50 is located around the opening 42 when the opening 42 is viewed in the direction T1, as illustrated in FIG. 4B. Thus, when the lid portion 50 is at the opening position, the lid portion 50 is not present on the path along which the vapor deposition material M released from the opening 42 reaches the vapor deposition target X. Thus, the opening position of the lid portion 50 is a position where the vapor deposition material M released from the opening 42 reaches the vapor deposition target X.

### Vapor Deposition Apparatus: Appendix

The vapor deposition apparatus 1 includes a single crucible 40, but is not limited thereto. For example, the vapor deposition apparatus 1 may include a plurality of the crucibles 40 in which the materials contained in the vapor deposition materials M stored in the interiors of the crucible bodies 41 are different from each other. In this case, the vapor deposition apparatus 1 may include the lid portion 50 and the lid holding portion 60 for each crucible 40.

The vapor deposition target X may be introduced into the vapor deposition apparatus 1 by using a transport device (not illustrated) including, for example, a conveyor. In this case, the transport device may be configured to transfer the vapor deposition target X in the interior of the vacuum chamber 10 while a surface of the vapor deposition target X on which the vapor deposition film is formed facing the crucible 40 side. In other words, the transport device may also function as the holding portion 20 that holds the vapor deposition material X in the interior of the vacuum chamber 10.

The vapor deposition apparatus 1 may include a control unit (not illustrated) that controls operations of the portions. The control unit may control, for example, evacuation of the interior of the vacuum chamber 10, movement of the shutter 30, heating of the crucible 40, and movement of the lid portion 50.

### Manufacturing Method for Display Device

Next, referring back to FIG. 1, the manufacturing method for the display device 100 according to the present embodiment will be described. As described above, the manufacturing method for the display device 100 according to the present embodiment includes a step of sequentially performing the film formation of the layers of the light-emitting element 102 on the substrate 101, and at least one layer of the layers of the light-emitting element 102 is formed using the vapor deposition apparatus 1.

In particular, in the case in which, in the light-emitting element 102, the function layer including the hole injection layer 104, the hole transport layer 105, the light-emitting layer 106, and the electron transport layer 107 contains an organic material, the function layer may be formed by the vapor deposition from the viewpoint of reducing deterioration of the function layer. In addition, also in the case in which the layer containing the organic material is vapor-deposited and then a new layer is further formed on the layer, the new layer may be formed by the vapor deposition from the viewpoint of reducing deterioration of the already formed layer.

In a film formation step of any layer of the light-emitting element 102 by using the vapor deposition apparatus 1, for example, a layered body including the substrate 101, in which layers from a layer to be formed to layers on the substrate 101 side are formed, is introduced, as the vapor deposition target X, into the interior of the vacuum chamber 10. Here, the layered body is placed on the arm 21 with a surface on which the vapor deposition film is formed facing a lower side, in other words, facing the crucible 40 side. Subsequently, the vapor deposition apparatus 1 evacuates the first space 16 and the second space 17 of the vacuum chamber 10 to bring the first space 16 and the second space 17 to a vacuum state.

Subsequently, the vapor deposition apparatus 1 heats the crucible 40 in which the material of a layer to be formed is stored as the vapor deposition material M in the interior of the crucible body 41, and sublimates the vapor deposition material M. Thus, the vapor deposition material M sublimated in the interior of the crucible 40 is released from the opening 42 of the crucible 40 toward the layered body that is the vapor deposition target X.

Here, when the vapor deposition apparatus 1 sets both the shutter 30 and the lid portion 50 to be at the opening position, the vapor deposition material M released from the opening 42 reaches a surface of the layered body. The vapor deposition material M that has reached the surface of the layered body is cooled by contact with the surface of the layered body and becomes solid again. Thus, a vapor deposition film containing the vapor deposition material M is formed on the surface of the layered body on the crucible 40 side.

Among the layers of the light-emitting element 102, for example, at least one of the anode 103 and the cathode 108 and the light-emitting layer 106 may be formed in an island shape for each subpixel on the substrate 101. In this case, the vapor deposition of each layer may be performed through a vapor deposition mask such as a metal mask that is disposed on the crucible 40 side of the layered body and includes openings at positions corresponding to the respective subpixels.

In the case in which the vapor deposition apparatus 1 includes the plurality of crucibles 40, in the method described above, a layer containing a plurality of materials may be formed by co-vapor deposition in which the plurality of crucibles 40 are heated at the same time to perform film formation.

In the manufacturing method for the display device 100 according to the present embodiment, at least one layer of the layers of the light-emitting element 102 may be formed by the vapor deposition using the vapor deposition apparatus 1. For example, in the manufacturing method for the display device 100 according to the present embodiment, some layers of the light-emitting element 102 may be formed by a method different from the vapor deposition, such as sputtering, a photolithography method, or an ink-jet method.

### Function of Lid Portion

In a vapor deposition step using the vapor deposition apparatus 1 according to the present embodiment, the release of the sublimated vapor deposition material M from the opening 42 is started from the time point when the crucible 40 is heated to a temperature necessary for sublimating the vapor deposition material M. However, due to non-uniform heating of the interior of the crucible body 41, a vapor deposition rate of the vapor deposition film formed on the vapor deposition target X may become unstable until the crucible 40 is sufficiently heated.

The vapor deposition rate refers to, for example, the thickness of the vapor deposition film formed on the vapor deposition target X per unit time, and corresponds to a film formation speed of the vapor deposition film on the vapor deposition target X.

In order to stabilize the vapor deposition rate, for example, it is conceivable to wait until the crucible 40 is sufficiently heated. During this time, in order to reduce contamination in the interior of the vacuum chamber 10, reduce consumption of the vapor deposition material M, or the like, the vapor deposition apparatus 1 moves the lid portion 50 to the blocking position to prevent the sublimated vapor deposition material M from reaching the vapor deposition target X. After the crucible 40 is sufficiently heated, the vapor deposition apparatus 1 moves the lid portion 50 from the blocking position to the opening position, and causes the sublimated vapor deposition material M to reach the vapor deposition target X. Thus, the vapor deposition apparatus 1 can perform the film formation of the vapor deposition film formed on the vapor deposition target X while stabilizing the vapor deposition rate.

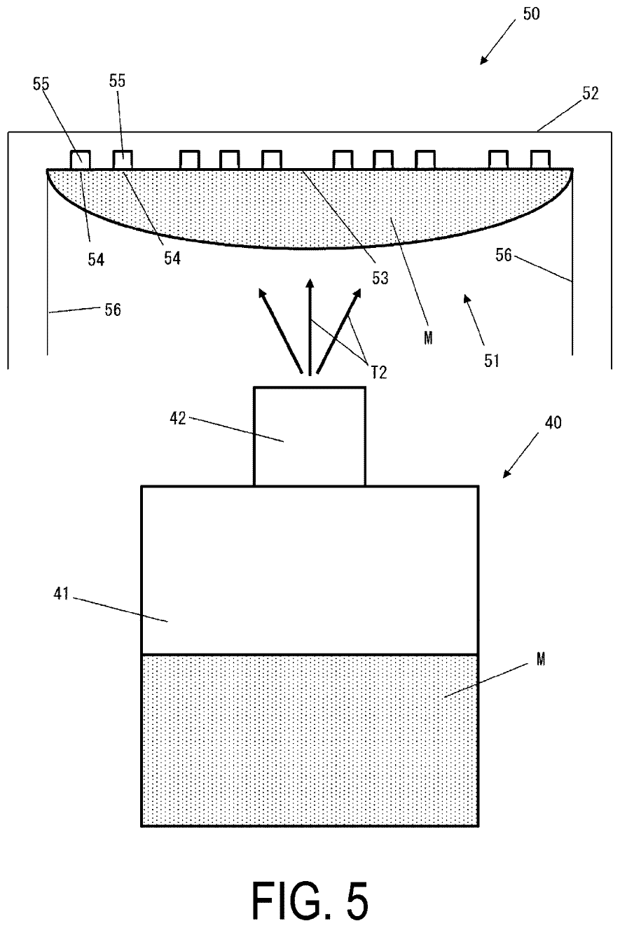

The principle of blocking the vapor deposition material M released from the opening 42 from reaching the vapor deposition target X by the lid portion 50 at the blocking position will be described in more detail with reference to FIG. 5. FIG. 5 is a schematic side cross-sectional view of the crucible 40 and the lid portion 50, illustrating a state in which the lid portion 50 blocks the vapor deposition material M released from the crucible 40 at the blocking position. For the sake of simplicity, portions of the vapor deposition apparatus 1 other than the crucible 40 and the lid portion 50 are not illustrated in FIG. 5.

When the crucible 40 is heated and the vapor deposition material M stored in the interior of the crucible body 41 is sublimated, the sublimated vapor deposition material M is released from the opening 42 toward a direction T2 that is a direction from the opening 42 toward the vapor deposition target X. Here, when the lid portion 50 is at the blocking position, the lid portion 50, particularly the top plate portion 53 of the lid portion 50, is located in the direction from the opening 42 toward the direction T2. Thus, when the vapor deposition material M is released from the opening 42 in a state in which the lid portion 50 is at the blocking position, the released vapor deposition material M comes into contact with the top plate portion 53, and is cooled on the top plate portion 53 to return to a solid. Thus, as illustrated in FIG. 5, the vapor deposition material M that is prevented from reaching the vapor deposition target X by the lid portion 50 is fixed to the lid portion 50, particularly, to the lower face of the top plate portion 53.

While the inner lid 51 is attached to the outer lid 52, the caps 55 close the holes 54. Thus, even when the vapor deposition material M released from the crucible 40 reaches a certain hole 54, the vapor deposition material M comes into contact with the lower face of a cap 55 closing the hole 54. Thus, the inner lid 51 reduces the fixation of the vapor deposition material M to the outer lid 52.

Further, in the vapor deposition step according to the present embodiment, the vapor deposition apparatus 1 may prevent the vapor deposition material M from reaching the vapor deposition target X by using the shutter 30 at the blocking position. However, from the viewpoint of reducing contamination in the interior of the vacuum chamber 10 and reducing the need for cleaning the vacuum chamber 10, the vapor deposition apparatus 1 may prevent the vapor deposition material M from reaching the vapor deposition target X mainly using the lid portion 50 that is closer to the crucible 40 than the shutter 30.

### Cleaning of Lid Portion

By continuously or intermittently heating the crucible 40 in a state in which the lid portion 50 is at the blocking position, the vapor deposition material M is accumulated on the lower face of the top plate portion 53. Thus, when the vapor deposition apparatus 1 is used, a cleaning step is performed in which the lid portion 50, particularly the inner lid 51, is periodically cleaned to remove the vapor deposition material M accumulated on the lower face of the top plate portion 53. Thus, it is possible to reduce contact of the vapor deposition material M accumulated on the lower face of the top plate portion 53 with the opening 42 or to reduce blocking of the opening 42.

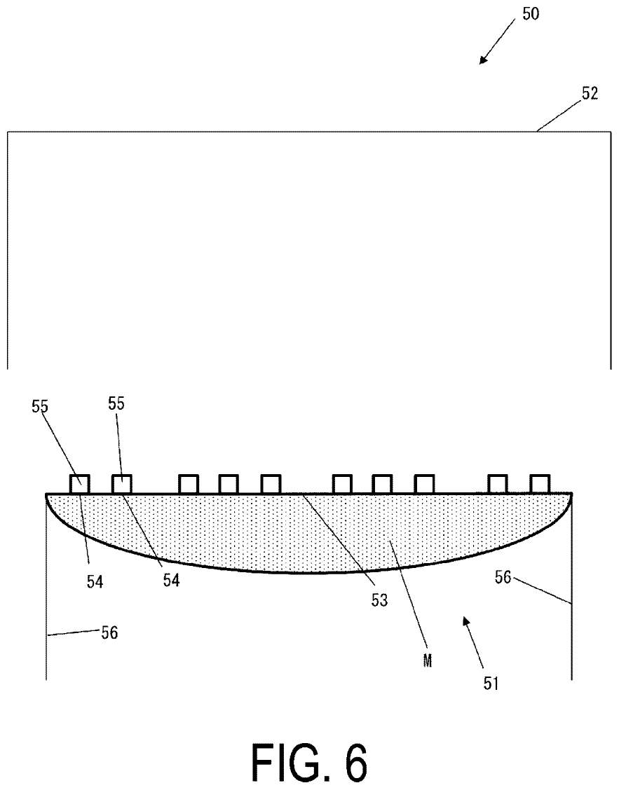

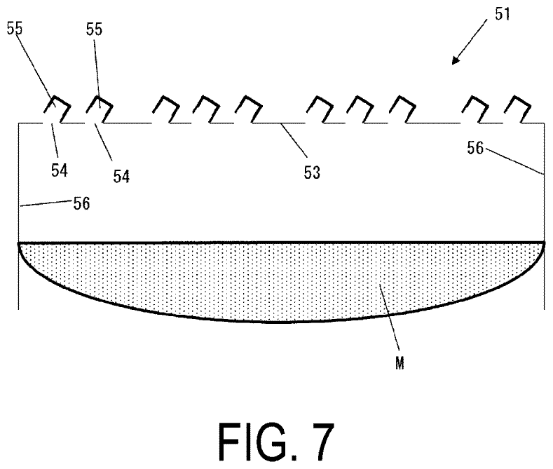

The cleaning step of the lid portion 50 will be described in detail with reference to FIGS. 6 and 7. FIG. 6 is a schematic cross-sectional view of the lid portion 50, illustrating a state in which the inner lid 51 is removed from the outer lid 52. FIG. 7 is a schematic cross-sectional view of the inner lid 51, illustrating a state in which the inner lid 51 is cleaned by removing the vapor deposition material M from the inner lid 51.

In the cleaning step of the lid portion 50, the lid portion 50 may be taken out of the vacuum chamber 10. In the cleaning step of the lid portion 50, for example, the beam 61 integrated with the outer lid 52 may be removed from the beam shaft 62. Further, in the cleaning step of the lid portion 50, as illustrated in FIG. 6, the inner lid 51 may be removed from the outer lid 52. Thereafter, another inner lid 51 from which the vapor deposition material M has been removed in advance may be attached to the outer lid 52, and the inner lid 51 may be disposed again in the interior of the vacuum chamber 10. Thus, even while the inner lid 51 is cleaned, it is possible to perform the vapor deposition step using the vapor deposition apparatus 1.

In the cleaning step of the lid portion 50, after the inner lid 51 is removed from the outer lid 52, the holes 54 are opened by, for example, rotating the caps 55 with respect to the top plate portion 53 as illustrated in FIG. 7. Thus, the air introduced through the holes 54 flows into a space between the top plate portion 53 and the vapor deposition material M fixed to the top plate portion 53. Thus, by operating the caps 55 to open the holes 54, the vacuum between the top plate portion 53 and the vapor deposition material M is broken, and the vapor deposition material M is separated from the top plate portion 53 by the vapor deposition material M's own weight as illustrated in FIG. 7. Air may be introduced into the hole 54 from a side of the top plate portion 53 opposite to a surface to which the vapor deposition material M adheres. In this case, the vapor deposition material M from the top plate portion 53 can be thoroughly removed.

Thus, the vapor deposition material M can be removed from the top plate portion 53. Subsequently, the holes 54 are closed by the operation of the caps 55 of the cleaned inner lid 51. Subsequently, the inner lid 51 is attached to the outer lid 52, and the lid portion 50 including the inner lid 51 and the outer lid 52 is attached to the interior of the vacuum chamber 10. Thus, the cleaning step of the lid portion 50 is completed.

### Summary of First Embodiment

The vapor deposition apparatus 1 according to the present embodiment includes the lid portion 50 that can block the vapor deposition material M released from the crucible 40 from reaching the vapor deposition target X. The lid portion 50 includes the top plate portion 53 with and to which the vapor deposition material M comes into contact and is fixed in the step of blocking the vapor deposition material M, the holes 54 that communicate through the top plate portion 53, and the caps 55 that close the holes 54 in an openable and closable manner. Thus, as described above, even when the vapor deposition material M is fixed to the top plate portion 53 of the lid portion 50, a large amount of the vapor deposition material M fixed to the top plate portion 53 can be removed at a time by operating the caps 55 to open the holes 54.

For example, as another method of removing the vapor deposition material from an object such as the lid portion to which the vapor deposition material is fixed, a method of directly scraping the vapor deposition material from the object by an elongated member such as a metal spoon is conceivable. In the cleaning by this method, the vapor deposition material needs to be removed from the object little by little by the elongated member, and the cleaning tends to take time.

In addition, in this method, a material such as a metal contained in the elongated member may be mixed into the recovered vapor deposition material due to contact of the vapor deposition material with the elongated member, and thus reuse of the vapor deposition material is difficult. Further, when the vapor deposition material is directly scraped from the object by the elongated member, the elongated member may also come into contact with the object, and there may be a problem such as generation of a scratch on the surface of the object and mixing of the material such as the metal contained in the elongated member into the scratch.

In the vapor deposition apparatus 1 according to the present embodiment, since the large amount of the vapor deposition material M can be removed from the lid portion 50 at a time by the cleaning step described above, the removal of the vapor deposition material M adhering to the lid portion 50 can be performed easily and in a short time, and the maintainability is improved. The cleaning step of the lid portion 50 can be performed only by operating the caps 55, and it is not necessary to bring another member into contact with the lid portion 50 or the vapor deposition material M. Thus, the vapor deposition apparatus 1 according to the present embodiment reduces the mixing of foreign matters into the vapor deposition material M removed by the cleaning step of the lid portion 50, facilitates the reuse of the vapor deposition material M, and reduces the contamination of the lid portion 50.

For example, as another method of removing the vapor deposition material M fixed to the inner side of the inner lid 51 of the lid portion 50, a method of forming a hole penetrating the side portion 56 in the side portion 56 and introducing air from the hole is conceivable. However, when air is introduced from the hole of the side portion 56, the vacuum between the vapor deposition material M and the top plate portion 53 may be maintained, and the vapor deposition material M may remain fixed to the top plate portion 53.

In the cleaning method of the lid portion 50 according to the present embodiment, the vacuum between the vapor deposition material M and the top plate portion 53 is broken, and thus the vapor deposition material M is more likely to be separated from the top plate portion 53 than in the method of introducing air through the hole of the side portion 56. Thus, the vapor deposition apparatus 1 according to the present embodiment includes the lid portion 50 including the holes 54 in the top plate portion 53, thereby further improving the maintainability of the lid portion 50 as compared with the case in which the lid including a through-hole in the side portion 56 is included.

In the manufacturing method for the display device 100 according to the present embodiment, the film formation of any layer of the light-emitting element 102 is performed using the vapor deposition apparatus 1 with improved maintainability, thereby improving the cost and the takt time. In addition, since the vapor deposition apparatus 1 used in the manufacturing method for the display device 100 reduces contamination of the lid portion 50, the manufacturing method reduces the mixing of foreign matters into the light-emitting element 102 and improves the quality of the light-emitting element 102.

### Appendix of First Embodiment

The lid portion 50 according to the present embodiment includes the inner lid 51 including the top plate portion 53 to which the vapor deposition material M is fixed, and the outer lid 52 that detachably supports the inner lid 51. Thus, even during the cleaning step of the inner lid 51, the vapor deposition apparatus 1 according to the present embodiment can perform the vapor deposition step using the lid portion 50 in which another inner lid 51 is attached to the outer lid 52.

The lid portion 50 according to the present embodiment includes the plurality of holes 54 and the plurality of caps 55, and each of the caps 55 closes a respective one of the holes 54 in an openable and closable manner. Thus, by opening the plurality of holes 54 at the same time in the cleaning step of the lid portion 50, the vapor deposition material M can be removed from the top plate portion 53 more reliably, and thus the vapor deposition apparatus 1 can reduce the amount of the vapor deposition material M remaining on the lid portion 50 in the cleaning step.

However, the cleaning step described above can be performed by opening any of the holes 54. Thus, the lid portion 50 may include at least one hole 54 and at least one cap 55 that closes the hole 54 in an openable and closable manner.

### Evaluation of Example and Comparative Example

In order to evaluate the maintainability of the vapor deposition apparatus 1 according to the present embodiment, the maintainability of a vapor deposition apparatus according to Example and the maintainability of a vapor deposition apparatus according to Comparative Example are compared.

The vapor deposition apparatus according to Example has the same configuration as the vapor deposition apparatus 1 according to the present embodiment including the lid portion 50. The vapor deposition apparatus according to Comparative Example includes only the inner lid 51 as the lid portion 50, and does not include the outer lid 52. Further, the inner lid 51 according to Comparative Example does not include the hole 54 and the cap 55. Except for the above points, the vapor deposition apparatus according to Comparative Example has the same configuration as the vapor deposition apparatus 1 according to the present embodiment.

In each of Example and Comparative Example, the film formation of the vapor deposition film by using the vapor deposition apparatus was performed until the cleaning step of the lid portion 50 was required, and then the cleaning step of the lid portion 50 was performed. In the cleaning step according to Example, as described above, the inner lid 51 was removed from the outer lid 52, the holes 54 were opened by the operation of the caps 55, and the removal of the vapor deposition material M from the top plate portion 53 was performed. In the cleaning step according to Comparative Example, the entire lid portion 50 was removed from the vapor deposition apparatus, and the removal of the vapor deposition material M from the top plate portion 53 was performed by scraping the vapor deposition material M adhering to the top plate portion 53 by using a metal spoon.

In each of Examples and Comparative Examples, for example, a weight of the inner lid 51 including the top plate portion 53 to which the vapor deposition material M was fixed or the lid portion 50 was measured prior to the cleaning step. Thus, in each of Example and Comparative Example, the weight of the vapor deposition material M fixed to the top plate portion 53 was calculated. In the cleaning step of each of Example and Comparative Example, the weight of the vapor deposition material M removed from the top plate portion 53 was measured while measuring an elapsed time from a start time point of the cleaning step. Thus, in the cleaning step of each of Example and Comparative Example, a ratio of the weight of the vapor deposition material M removed from the top plate portion 53 to the weight of the vapor deposition material M fixed to the top plate portion 53 was calculated for each elapsed time from the start time point.

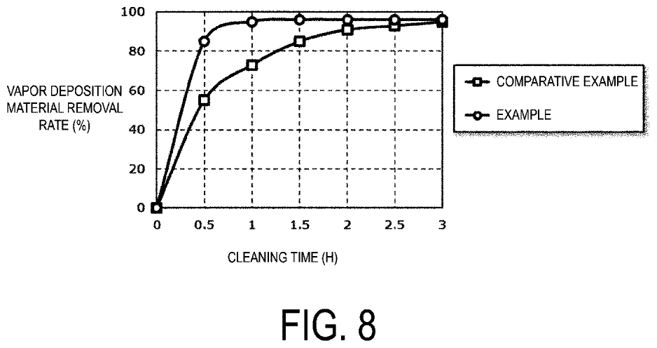

A relationship between a cleaning time and a removal rate of the vapor deposition material in each of Example and Comparative Example will be described with reference to FIG. 8. FIG. 8 is a graph showing the relationship between the cleaning time and the removal rate of the vapor deposition material. In the graph of FIG. 8, the horizontal axis represents the cleaning time, in other words, the time (unit: hour) for performing the cleaning step, and the vertical axis represents the vapor deposition material removal rate, in other words, a ratio in percentage of the weight of the vapor deposition material M removed from the top plate portion 53 to a total weight of the vapor deposition material M fixed to the top plate portion 53. In the graph of FIG. 8, the measured values in Example are plotted with circles, the measured values in Comparative Example are plotted with squares, and complementary lines between the plots of Example and between the plots of Comparative Example are also shown.

In the cleaning step according to Example, 80% or more of the vapor deposition material M was removed at the time point when 30 minutes had elapsed from the start, and the removal of most of the vapor deposition material M was completed after one hour had elapsed from the start. On the other hand, in the cleaning step according to Comparative Example, the removal rate of the vapor deposition material M is less than 80% even at the time point when one hour has elapsed from the start. Thus, the vapor deposition apparatus according to Example can remove a larger amount of the vapor deposition material M from the lid portion 50 in a shorter time than the vapor deposition apparatus according to Comparative Example, and thus the maintainability is improved.

In addition, since the vapor deposition material M removed in the cleaning step according to Example is prevented from coming into contact with other members, the possibility of the mixing of the foreign matters is low, and the reuse of the removed vapor deposition material M is easy. On the other hand, since the metal material of the spoon may be mixed into the vapor deposition material M removed in the cleaning step according to Comparative Example, the reuse of the removed vapor deposition material M is difficult.

Further, in the cleaning step according to Example, since contact between the top plate portion 53 and other members is avoided, contamination of the top plate portion 53 is reduced. Thus, by using the vapor deposition apparatus including the lid portion 50 in which the inner lid 51 including the top plate portion 53 is attached to the outer lid 52 again, a vapor deposition film in which the mixing of foreign matters is reduced can be formed. On the other hand, in the cleaning step according to Comparative Example, the top plate portion 53 and the spoon come into contact with each other, and thus the top plate portion 53 may be contaminated. Thus, in the film formation step of the vapor deposition film by using the vapor deposition apparatus including the lid portion 50 including the top plate portion 53, foreign matters may be mixed into the vapor deposition film.

In the cleaning step according to Example, the inner lid 51 is only removed from the outer lid 52 and cleaned, and thus the film formation of the vapor deposition film by using the vapor deposition apparatus can be performed by attaching another inner lid 51 to the outer lid 52 even during the cleaning step. On the other hand, in the cleaning step according to Comparative Example, since the lid portion 50 is removed from the vapor deposition apparatus, it is difficult to perform the film formation of the vapor deposition film by using the vapor deposition apparatus during the cleaning step.

As described above, the vapor deposition apparatus according to Example improves maintainability, facilitates the reuse of the vapor deposition material, reduces mixing of foreign matters into the vapor deposition film, and facilitates simultaneous execution of the cleaning step and the vapor deposition step, as compared with the vapor deposition apparatus according to Comparative Example.

### Second Embodiment

### Partition of Lid Portion

Another embodiment of the disclosure will be described with reference to the drawings. The vapor deposition apparatus 1 according to the present embodiment differs in configuration from the vapor deposition apparatus 1 according to the previous embodiment only in that the vapor deposition apparatus 1 includes a lid portion 70 instead of the lid portion 50.

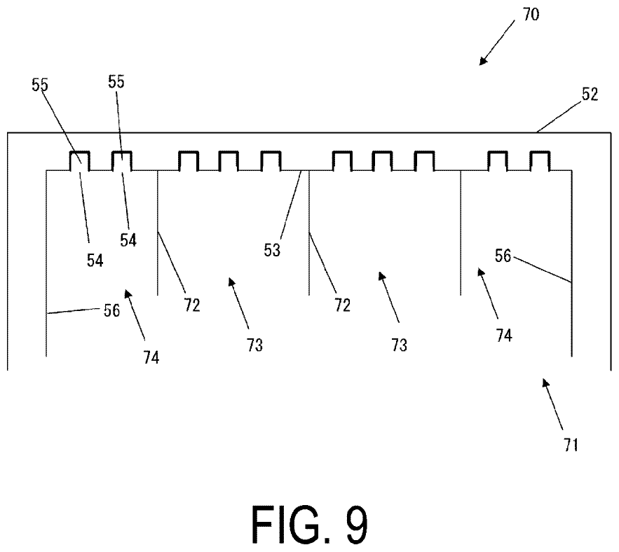

The lid portion 70 according to the present embodiment will be described in more detail with reference to FIG. 9. FIG. 9 is a schematic side cross-sectional view of the lid portion 70 according to the present embodiment.

As illustrated in FIG. 9, the lid portion 70 according to the present embodiment differs in configuration from the lid portion 50 according to the previous embodiment only in that the lid portion 70 includes an inner lid 71 instead of the inner lid 51. The inner lid 71 according to the present embodiment differs in configuration from the inner lid 51 according to the previous embodiment only in that the inner lid 71 further includes a partition 72 formed on the top plate portion 53. For example, also in the present embodiment, the outer lid 52 detachably supports the inner lid 71.

The partition 72 projects from the top plate portion 53 in substantially the same direction as a direction in which the side portion 56 projects from the top plate portion 53. In other words, in a state in which the lid portion 70 is at the blocking position, the partition 72 projects from the surface of the top plate portion 53 on the opening 42 side. In addition, in a state in which the lid portion 70 is at the blocking position, the partition 72 partitions a space on the opening 42 side into a plurality of spaces.

Thus, as illustrated in FIG. 9, the lid portion 70 is partitioned into a plurality of regions including a plurality of first regions 73 and a plurality of second regions 74 by the partitions 72. Here, each region of the lid portion 70 partitioned by the partition 72 refers to a region including the partition 72 or the side portion 56, and the top plate portion 53 surrounded by the partition 72 and the side portion 56. In the present embodiment, an area of the top plate portion 53 in each first region 73 is larger than an area of the top plate portion 53 in each second region 74.

Further, the lid portion 70 includes at least one hole 54 and a cap 55 that closes the hole 54 in an openable and closable manner in each of the plurality of regions partitioned by the partition 72. In particular, the lid portion 70 according to the present embodiment includes the plurality of holes 54 in at least one of the plurality of regions partitioned by the partition 72. For example, each of the first regions 73 and each of the second regions 74 include the plurality of holes 54 and the plurality of caps 55 that close the holes 54 in an openable and closable manner. Here, the number of the holes 54 included in each first region 73 is larger than the number of the holes 54 included in each second region 74.

The manufacturing method for the display device 100 using the vapor deposition apparatus 1 according to the present embodiment is the same method as the manufacturing method for the display device 100 using the vapor deposition apparatus 1 according to the previous embodiment except that the lid portion 50 is replaced with the lid portion 70. Thus, even in the manufacturing method for the display device 100 using the vapor deposition apparatus 1 according to the present embodiment, the vapor deposition material M that is blocked from reaching the vapor deposition target X by the lid portion 70 may be fixed to the top plate portion 53 of the inner lid 71 of the lid portion 70.

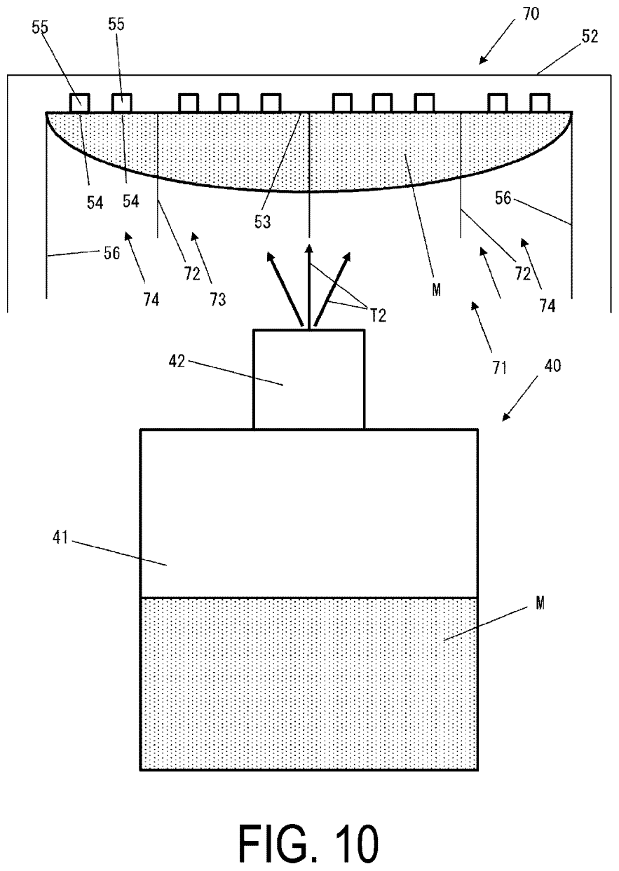

A state in which the lid portion 70 at the blocking position blocks the vapor deposition material M released from the opening 42 from reaching the vapor deposition target X will be described in more detail with reference to FIG. 10. FIG. 10 is a schematic side cross-sectional view of the crucible 40 and the lid portion 70, illustrating a state in which the lid portion 70 blocks the vapor deposition material M released from the crucible 40 at the blocking position. For the sake of simplicity, portions of the vapor deposition apparatus 1 other than the crucible 40 and the lid portion 70 are not illustrated in FIG. 10.

When the lid portion 70 at the blocking position blocks the vapor deposition material M released from the opening 42, the vapor deposition material M is fixed to the top plate portion 53 of the lid portion 70 by the same principle as the fixing of the vapor deposition material M to the top plate portion 53 of the lid portion 50. Here, in the present embodiment, the vapor deposition material M blocked by the lid portion 70 reaches the top plate portion 53 of each of the plurality of regions partitioned by the partition 72. Thus, the vapor deposition material M fixed to the top plate portion 53 of the lid portion 70 is partitioned into a plurality of pieces by the partition 72.

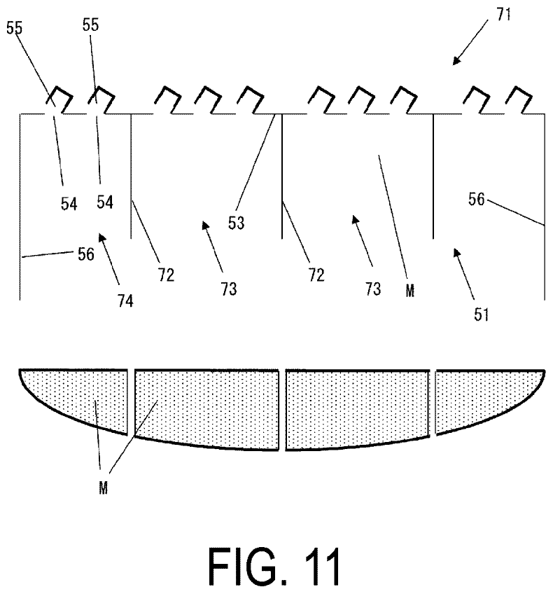

Also, when the vapor deposition apparatus 1 according to the present embodiment is used, the cleaning step is performed in which the lid portion 70, particularly the inner lid 71, is periodically cleaned to remove the vapor deposition material M accumulated on the lower face of the top plate portion 53. The cleaning step of the lid portion 70 will be described in detail with reference to FIG. 11. FIG. 11 is a schematic cross-sectional view of the inner lid 71, illustrating a state in which the inner lid 71 is cleaned by removing the vapor deposition material M from the inner lid 71.

Also, in the cleaning step of the lid portion 70, the inner lid 71 may be removed from the outer lid 52 after the lid portion 70 is taken out of the vacuum chamber 10. Subsequently, as illustrated in FIG. 11, the hole 54 is opened, and thus the vapor deposition material M is separated from the top plate portion 53 by the vapor deposition material M's own weight by the same principle as the principle described in the previous embodiment. Thereafter, the holes 54 are closed by the operation of the caps 55, the inner lid 71 is attached to the outer lid 52, and the lid portion 70 is attached to the interior of the vacuum chamber 10, and thus the cleaning step of the lid portion 70 is completed.

Here, since the vapor deposition material M is partitioned by the partition 72 as described above, the vapor deposition material M fixed to the top plate portion 53 is divided into a plurality of pieces as illustrated in FIG. 11. The lid portion 70 includes at least one hole 54 in each of the regions divided by the partition 72. Thus, the removal of the vapor deposition material M in the cleaning step according to the present embodiment is performed by the separation of each of the vapor deposition materials M from the top plate portion 53 due to the own weight on each of the divided vapor deposition materials M. Thus, the lid portion 70 according to the present embodiment can reduce the possibility that a part of the vapor deposition material M remains without being separated from the top plate portion 53 in the cleaning step, as compared with the lid portion 50 according to the previous embodiment.

In particular, the lid portion 70 according to the present embodiment includes the plurality of holes 54 in at least one of the plurality of regions partitioned by the partition 72. Thus, the lid portion 70 according to the present embodiment can reduce the amount of the vapor deposition material M remaining in the region in the cleaning step.

However, the cleaning step described above can be performed by opening any one of the holes 54 in each of the regions of the lid portion 70. Thus, the lid portion 70 may include at least one hole 54 and the cap 55 that closes a respective one of the holes 54 in an openable and closable manner in each region of the lid portion 70.

In the present embodiment, the number of holes 54 located in the first region 73 of the plurality of regions of the lid portion 70 is larger than the number of holes 54 located in the second region 74 in which the area of the top plate portion 53 is smaller than that in the first region 73. In the cleaning step according to the present embodiment, the larger the number of the holes 54 per unit area of the top plate portion 53 in each region of the lid portion 70, the more the amount of the vapor deposition material M remaining on the top plate portion 53 in the region can be reduced. Thus, with the above configuration, the lid portion 70 can efficiently reduce the vapor deposition material M remaining on the top plate portion 53 in both the first region 73 and the second region 74.

### Third Embodiment

### Bolt

Further embodiments of the disclosure will be described with reference to the drawings. The vapor deposition apparatus 1 according to the present embodiment differs in configuration from the vapor deposition apparatus 1 according to the first embodiment only in that the vapor deposition apparatus 1 includes a lid portion 80 instead of the lid portion 50.

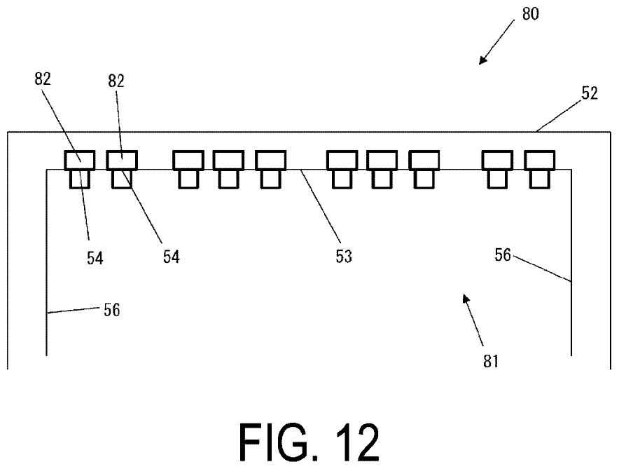

The lid portion 80 according to the present embodiment will be described in more detail with reference to FIG. 12. FIG. 12 is a schematic side cross-sectional view of the lid portion 80 according to the present embodiment.

As illustrated in FIG. 12, the lid portion 80 according to the present embodiment differs in configuration from the lid portion 50 according to the first embodiment only in that the lid portion 80 includes an inner lid 81 instead of the inner lid 51. The inner lid 81 according to the present embodiment includes a plurality of bolts 82 instead of the caps 55, as compared with the inner lid 51 according to the first embodiment. For example, also in the present embodiment, the outer lid 52 detachably supports the inner lid 81.

The bolts 82 are insertable into and removable from the holes 54, respectively, and close the holes 54 by being inserted into the holes 54. Thus, the bolt 82 functions as a cap that opens and closes the hole 54 by being inserted into and removed from the hole 54.

The manufacturing method for the display device 100 using the vapor deposition apparatus 1 according to the present embodiment is the same method as the manufacturing method for the display device 100 using the vapor deposition apparatus 1 according to the previous embodiment except that the lid portion 50 is replaced with the lid portion 80. Also, when the vapor deposition apparatus 1 according to the present embodiment is used, the cleaning step is performed in which the lid portion 80, particularly the inner lid 81, is periodically cleaned to remove the vapor deposition material M accumulated on the lower face of the top plate portion 53. The cleaning step of the lid portion 80 according to the present embodiment is performed by the same method as the cleaning step of the lid portion 50 according to the first embodiment except that the operation of the cap 55 is replaced with the insertion and removal of the bolt 82.

For example, in the cleaning step of the lid portion 80 according to the present embodiment, the bolts 82 are pulled out from the holes 54 to open the holes 54, thereby removing the vapor deposition material M adhering to the inner lid 81 from the inner lid 81. In the cleaning step, the bolts 82 are then inserted into the holes 54 to close the holes 54.

The lid portion 80 according to the present embodiment includes the bolts 82 that achieve opening and closing of the holes 54 by being inserted and removed, as compared with the lid portion according to the above-described embodiments. Thus, the lid portion 80 can reduce the number of mechanisms for the operation of the caps and opening and closing of the holes 54 by the operation, such as a rotation mechanism formed in the top plate portion 53. Thus, the lid portion 80 can perform the cleaning step with a simpler configuration, and the maintainability is improved.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in the embodiments.

1. (canceled)

2. A vapor deposition apparatus comprising:
a crucible including an opening configured to release a vapor deposition material toward a vapor deposition target; and
a lid portion configured to move between a blocking position, the vapor deposition material being prevented from reaching the vapor deposition target at the position and an opening position, the vapor deposition material reaching the vapor deposition target at the position,
wherein the lid portion includes
a top plate portion overlapping the opening when the opening is viewed from a position where the vapor deposition target is disposed when the lid portion is at the blocking position,
at least one hole communicating through the top plate portion, and
at least one cap configured to close the hole in an openable and closable manner,
the lid portion further includes
an inner lid including the top plate portion, the hole, and the cap, and
an outer lid configured to detachably attach the inner lid and support the inner lid on a side opposite to the opening with respect to the inner lid in a state in which the lid portion is at the blocking position.

3. A vapor deposition apparatus comprising:
a crucible including an opening configured to release a vapor deposition material toward a vapor deposition target; and
a lid portion configured to move between a blocking position, the vapor deposition material being prevented from reaching the vapor deposition target at the position and an opening position, the vapor deposition material reaching the vapor deposition target at the position,
wherein the lid portion includes
a top plate portion overlapping the opening when the opening is viewed from a position where the vapor deposition target is disposed when the lid portion is at the blocking position,
at least one hole communicating through the top plate portion, and
at least one cap configured to close the hole in an openable and closable manner,
the lid portion further includes
a plurality of the holes and
a plurality of caps each configured to close a respective one of the holes in an openable and closable manner.

4. The vapor deposition apparatus according to claim 3,
wherein the lid portion includes a partition projecting from a surface of the top plate portion on a side of the opening in a state of being at the blocking position and configured to partition a space on the side of the opening into a plurality of spaces, and
the lid portion includes at least one of the holes in each of a plurality of regions partitioned by the partition.

5. The vapor deposition apparatus according to claim 4,
wherein the lid portion includes the plurality of holes in at least one of the regions.

6. The vapor deposition apparatus according to claim 5,
wherein the number of the holes located in a first region of the plurality of regions is larger than the number of the holes located in a second region of the plurality of regions, the second region having a smaller area of the top plate portion than the first region.

7. The vapor deposition apparatus according to claim 2,
wherein the cap closes the hole by being inserted into the hole.

8. A manufacturing method for a display device including a plurality of light-emitting elements each including a first electrode, a second electrode, and a function layer including at least a light-emitting layer between the first electrode and the second electrode, the manufacturing method comprising:
forming at least one of the first electrode, the second electrode, and the function layer by using the vapor deposition apparatus according to claim 2.
